(19) United States
(12) Patent Application Publication
(10) Pub. No.: US 2025/0257465 A1
(43) Pub. Date: Aug. 14, 2025

(54) RAPID PROCESS FOR VAPOR-DEPOSITED ZIF-8 METAL ORGANIC FRAMEWORK (MOF) FOR LOW-K DIELECTRIC SEAMLESS HIGH ASPECT RATIO GAP FILL

(71) Applicants: SAMSUNG ELECTRONICS CO., LTD., Suwon-si (KR); The Regents of The University of California, Oakland, CA (US)

(72) Inventors: Dipayan PAL, San Diego, CA (US); Naeun YANG, San Diego, CA (US); Andrew C. KUMMEL, La Jolla, CA (US); Harsono SIMKA, San Jose, CA (US); Jacob WATSON, La Jolla, CA (US)

(73) Assignees: SAMSUNG ELECTRONICS CO., LTD., Suwon-si (KR); The Regents of The University of California, Oakland, CA (US)

(21) Appl. No.: 19/048,574

(22) Filed: Feb. 7, 2025

Related U.S. Application Data
(60) Provisional application No. 63/673,664, filed on Jul. 19, 2024.
(60) Provisional application No. 63/551,696, filed on Feb. 9, 2024.

(51) Int. Cl. C23C 16/56; C23C 14/18; C23C 16/40; C23C 16/455; H01L 21/02; H01L 21/768

(52) U.S. Cl. CPC C23C 16/56; C23C 16/407; C23C 16/45529; C23C 14/18; H01L 21/02175; H01L 21/0228; H01L 21/76837

(57) ABSTRACT

A process for forming a vapor-deposited ZIF-8 metal organic framework includes: conducting a gas surface reaction between an ALD-deposited ZnO and 2-methylimidazole to form a vapor-deposited ZIF-8 metal organic framework, wherein the gas surface reaction is conducted at a temperature greater than 140 C, and wherein the gas surface reaction is conducted at a pressure of less than 1000 mTorr. In a particular embodiment, the gas surface reaction is conducted at a temperature of 160 C. A process for preparing a laminate includes: performing ALD of zinc oxide as a base between 1 nm to 10 nm in thickness, exposing 2-methylimidazole vapor phase linker at chemical vapor deposition at a temperature range of greater than 140 C to less than or equal to 180 C in a vacuum condition, and cycling of the ZnO ALD and 2-methylimidazole exposure to deposit a film or fill a gap.

### CROSS-REFERENCE TO RELATED APPLICATIONS

This application is based on and claims priority from U.S. Provisional Application No. 63/551,696 filed on Feb. 9, 2024 and U.S. Provisional Application No. 63/673,664 filed on Jul. 19, 2024 in the U.S. Patent and Trademark Office, the disclosures of which are incorporated herein by reference in their entirety.

### BACKGROUND

### 1. Field

The present disclosure concerns a rapid process for a vapor-deposited ZIF-8 metal organic framework (MOF). Also, the present disclosure concerns a process for preparing a laminate.

### 2. Description of the Related Art

The potential of MOFs as low-k dielectrics has been recognized, with a straightforward Clausius-Mossotti model being used to predict the dielectric constants of several MOFs. ZIF-8 films are thermally and chemically stable metal-organic framework (MOF) made up of Zn(II) nodes and an organic linker called 2-methylimidazolate. An experimental validation of the low k-value of solution-deposited ZIF-8 films (k=2.33) has been presented. Since then, several MOFs were researched as possible low-k dielectrics. Initially, all documented procedures for ZIF-8 MOF thin films were based on powder synthesis processes, which involved combining linkers and metal salts in an organic solvent, usually under solvothermal conditions. As a result, it was unsuitable for microelectronics fabrication infrastructure and challenging to scale. Yet, new breakthroughs in the vapor-phase deposition of MOF films (e.g., UiO-66 MOF) filled this gap and allowed inclusion in on-chip interconnects.

A recent study found modest gap fill properties for vapor-deposited ZIF-8 MOF films with k as low as ˜2.2 and breakdown at 0.5 MV/cm. The study used ALD of ˜6 nm ZnO followed by exposure to 2-methylimidazole vapor phase linker at CVD temperature of 120° C. Starting with ˜6 nm ALD ZnO, the conversion was observed to yield ˜24 nm ZIF-8, which corresponded to a remarkably low thickness expansion factor of only 4×. Fork-fork capacitors were used to test gap filling with MOF-CVD ZIF-8, which began with a 6 nm ALD ZnO layer. The ZIF-8 phase appears to be gap-filled in the 45 nm wide trenches; however, there is significant evidence of an unconverted ZnO underlayer within the trenches, which looks to be a key limitation of the study. This could be attributed to the poor vacuum, as 7.5 Torr was used for the CVD MOF conversion setup. Also, the process time was also quite long, namely, 2 hours for one MOF conversion cycle.

Consequently, it is essential to fully convert ZnO to MOF with controlled grain size and optimize the process to deposit MOFs with the best electrical, mechanical, and thermal properties in order to produce seamless thin gap-fill dielectrics for semi-damascene dielectrics, dielectric infill, and packaging applications. In addition, it is necessary to develop a fast MOF process so that it would be compatible with the microelectronics industry fabrication.

Information disclosed in this Background section has already been known to the inventors before achieving the disclosure of the present application or is technical information acquired in the process of achieving the disclosure. Therefore, it may contain information that does not form the prior art that is already known to the public.

### SUMMARY

In logic, low k dielectrics (also known as interlayer dielectrics, ILD) with the necessary thermal, electrical, and mechanical properties must be inserted into M1 and M2 and as well as upper interconnect layers. For semi-damascene processing, it is desirable to have a low k dielectric deposited by a thermal process which can achieve gap fill in high aspect ratio features. MOFs (such as zeolitic imidazolate frameworks, ZIF-8) can be formed through a gas surface reaction between an ALD-deposited ZnO and an organic linker (2-methylimidazole), resulting in a structured material with an open fraction of up to 70%, which can significantly reduce interconnect capacitance due to its low-k dielectric and appropriate mechanical strength. ZIF-8 MOFs can exhibit Young's modulus comparable to the state-of-the-art porous organosilanes (OSG) and dielectric constants as low as ˜2-2.5. These MOFs can have a thermal conductivity as high as 1 W/m-K and a reported breakdown field of around 0.5 MV/cm; however, it is hypothesized that the breakdown field can be increased by optimizing MOF process conditions.

MOF infill may also be used in thermal compression bonding for infill dielectric in chiplet-to-chiplet or chiplet-to-wafer bonding. At present, after copper bonding, the gap is filled by polymer or epoxy. The vapor phase MOF process would allow a small gap and tighter pitch Cu since it can fill extremely side aspect ratio features via a fast low-temperature reflow process described below.

In the present disclosure, a rapid novel process of vapor phase ZIF-8 MOF deposition is reported with significantly lower process time (15 min only) at 160° C. CVD process temperature. This is the fastest reported vapor process to form a MOF film, and it was enabled by the high processing temperature and a low background H₂O environment. This process demonstrated complete ZnO to MOF conversion and demonstrated MOFs for low-k for seamless thin gap-fill dielectrics. Parallel plate capacitors were fabricated, and k value was estimated to be about 2.6 and the device was stable over months. Breakdown was found out to be 0.7 MV/cm, which is higher than that of the earlier reported value, 0.5 MV/cm. Thermal stability of MOF was also tested which showed MOF was stable up to 450° C. under vacuum (1E-6 Torr). Plasma etch test was also demonstrated for the first time for MOF 160 C vs. bare Si, SiCOH, and SiO₂. The etch rate was the following: SiCOH>Bare Si>SiO₂>MOF 160 C. MOF 160 C was the best to resist plasma etch. The process temperature might be increased to 170 or 180 C with a better vacuum system.

In various embodiments of the present disclosure are herein described the use of vapor-deposited films of metal-organic frameworks (MOFs) such as zeolitic imidazolate frameworks (ZIF-8) as ultra-low-k dielectrics. In some embodiments, such MOFs films may have the thermal, electrical, and mechanical properties to be used in the back-end-of-line (BEOL) interconnects. In some embodiments the use of semi-damascene BEOL opens an opportunity for vapor phase deposited interlayer dielectrics (ILD) of sub-100 nm thickness which can fill in narrow trenches. In some embodiments MOFs can be formed by a gas surface reaction between an atomic-layer deposited (ALD) metal oxide and an organic precursor to create a structured material with an open fraction as high as 70%, which can in some embodiments decrease interconnect capacitance by having a low dielectric value, while having a reasonable mechanical strength. The disclosure includes various embodiments of a robust process of vapor phase MOF deposition which may ensure complete, or substantially complete, ZnO to MOF conversion with controlled grain size and identify MOFs with (i) ultra-low-k value, and (ii) ability to gap-fill narrow and wide features for semi-damascene.

Thus, a first embodiment of the present disclosure provides a process for forming a vapor-deposited ZIF-8 metal organic framework, referred to as ALD-ZnO+soak cycle, comprising:
conducting a gas surface reaction between an ALD-deposited ZnO and 2-methylimidazole to form a vapor-deposited ZIF-8 metal organic framework;
wherein the gas surface reaction is conducted at a temperature greater than 140 C, and
wherein the gas surface reaction is conducted at a pressure of less than 1000 mTorr.

A second embodiment of the present disclosure provides a process according to the first embodiment, wherein the gas surface reaction is conducted at a temperature greater than 140 C and less than or equal to 180 C.

A third embodiment of the present disclosure provides a process according to the first embodiment, wherein the gas surface reaction is conducted at a temperature greater than 140 C and less than or equal to 175 C.

A fourth embodiment of the present disclosure provides a process according to the first embodiment, wherein the gas surface reaction is conducted at a temperature greater than or equal to 160 C and less than or equal to 180 C.

A fifth embodiment of the present disclosure provides a process according to the first embodiment, wherein the gas surface reaction is conducted at a temperature greater than or equal to 160 C and less than or equal to 175 C.

A sixth embodiment of the present disclosure provides a process according to the first embodiment, wherein the gas surface reaction is conducted at a temperature of 160 C.

A seventh embodiment of the present disclosure provides a process according to the first embodiment, wherein the gas surface reaction is conducted for less than 1 hour.

An eighth embodiment of the present disclosure provides a process according to the sixth embodiment, wherein the gas surface reaction is conducted for 15 minutes.

A ninth embodiment of the present disclosure provides a process according to the first embodiment, wherein the gas surface reaction is conducted at a pressure of less than or equal to about 900 mTorr.

A tenth embodiment of the present disclosure provides a process according to the sixth embodiment, wherein the gas surface reaction is conducted at a pressure of about 900 mTorr.

An eleventh embodiment of the present disclosure provides a process according to the sixth embodiment, wherein the gas surface reaction is conducted at a pressure of about 750 mTorr.

A twelfth embodiment of the present disclosure provides a process according to the first embodiment, wherein the ALD-deposited ZnO is in a ZnO seed layer having a thickness of up to 5 nm.

A thirteenth embodiment of the present disclosure provides a process according to the sixth embodiment, wherein the ALD-deposited ZnO is in a ZnO seed layer having a thickness of up to 5 nm.

A fourteenth embodiment of the present disclosure provides a process according to the first embodiment, wherein the process is conducted plural times to form a nanolaminates structure.

A fifteenth embodiment of the present disclosure provides a process according to the sixth embodiment, wherein the process is conducted plural times to form a nanolaminates structure.

A sixteenth embodiment of the present disclosure provides a process according to the twelfth embodiment, wherein the process is conducted plural times to form a nanolaminates structure.

A seventeenth embodiment of the present disclosure provides a process according to the thirteenth embodiment, wherein the process is conducted plural times to form a nanolaminates structure.

An eighteenth embodiment of the present disclosure provides a process according to the sixth embodiment, wherein the vapor-deposited ZIF-8 metal organic framework is subjected to chemical mechanical polishing after being formed.

A nineteenth embodiment of the present disclosure provides a process for fabricating a semiconductor device, comprising providing a vapor-deposited ZIF-8 metal organic framework formed by the process of the sixth embodiment as an interconnect dielectric.

A twentieth embodiment of the present disclosure provides a process for thermal compression bonding, comprising providing a vapor-deposited ZIF-8 metal organic framework formed by the process of the sixth embodiment as an infill dielectric in chiplet-to-chiplet or chiplet-to-wafer thermal compression bonding.

A twenty-first embodiment of the present disclosure provides a process according to the sixth embodiment, wherein the ALD-deposited ZnO is in a ZnO seed layer having a thickness of 3 nm.

A twenty-second embodiment of the present disclosure provides a process for preparing a laminate, comprising: performing ALD of zinc oxide as a base between 1 nm to 10 nm in thickness, exposing 2-methylimidazole vapor phase linker at chemical vapor deposition at a temperature range of greater than 140 C to less than or equal to 180 C in a vacuum condition, and cycling of the ZnO ALD and 2-methylimidazole exposure to deposit a film or fill a gap.

A twenty-third embodiment of the present disclosure provides a process according to the twenty-second embodiment, wherein the thickness of the zinc oxide as a base is up to 5 nm.

A twenty-fourth embodiment of the present disclosure provides a process according to the twenty-second embodiment, wherein the thickness of the zinc oxide as a base is 5 nm.

A twenty-fifth embodiment of the present disclosure provides a process according to the twenty-second embodiment, wherein the thickness of the zinc oxide as a base is 3 nm.

A twenty-sixth embodiment of the present disclosure provides a process according to the twenty-second embodiment, wherein the exposing is at a temperature range of greater than or equal to 150 C and less than or equal to 180 C.

A twenty-seventh embodiment of the present disclosure provides a process according to the twenty-second embodiment, wherein the exposing is at a temperature range of greater than or equal to 160 C and less than or equal to 180 C.

A twenty-eighth embodiment of the present disclosure provides a process according to the twenty-second embodiment, wherein the exposing is at a temperature of 160 C.

A twenty-ninth embodiment of the present disclosure provides a process according to the first embodiment, wherein the ALD-deposited ZnO is Zn-rich ZnO.

A thirtieth embodiment of the present disclosure provides a process according to the first embodiment, wherein the ALD-ZnO+soak cycle further comprises Al, wherein the Al is present in a content <10%.

A thirty-first embodiment of the present disclosure provides a process according to the twenty-second embodiment, wherein the zinc oxide is Zn-rich zinc oxide.

A thirty-second embodiment of the present disclosure provides a process according to the twenty-second embodiment, wherein the ALD-ZnO+soak cycle further comprises Al, wherein the Al is present in a content of <10%.

A thirty-third embodiment of the present disclosure provides a process according to the twenty-second embodiment, further comprising performing physical vapor deposition (PVD) of Ti prior to performing zinc oxide ALD, wherein the PVD forms a Ti film having a thickness <1 nm.

A thirty-fourth embodiment of the present disclosure provides a process according to the twenty-second embodiment, wherein the zinc oxide is either at the bottom of features or at the bottom and sidewalls of features only.

A thirty-fifth embodiment of the present disclosure provides a process according to the first embodiment, wherein the gas surface reaction is conducted at a pressure of less than or equal to about 1 mTorr, facilitated by a turbo vacuum pump with a pumping capacity in liters per second (L/s) ranging from 50 L/s to 1000 L/s.

### BRIEF DESCRIPTION OF DRAWINGS

The patent or application file contains at least one drawing executed in color. Copies of this patent or patent application publication with color drawing(s) will be provided by the Office upon request and payment of the necessary fee.

Example embodiments of the present disclosure will be more clearly understood from the following detailed description taken in conjunction with the accompanying drawing in which:

FIGS. 1A-1D are TEM images of MOF gap fill processes from literature (FIGS. 1A-1B) vs the present disclosure (FIGS. 1C-1D).

FIGS. 2A-2B show 160 C as optimal ZnO to ZIF-8 MOF conversion temperature.

FIG. 3 shows that the MOF 160 C process results in the smaller features filling first and the larger features filling for the corners first.

FIGS. 4A-4C show the failure of MOF 140 C as gap fill.

FIGS. 5A-5C show the k value, breakdown, and air stability for MOF 160° C. film.

FIGS. 6A-6C show the structure and morphology of MOF 160 C, and comparison with that of 120 C and 140 C.

FIG. 7 shows a schematic of a CHF₃ plasma etch test for MOF 160 C.

FIG. 8 is a graph showing the results of a thermal stability test of MOF 160 C.

FIGS. 9A-9B show another embodiment of the present disclosure, in which 1 nm ALD ZnO and then conversion to MOF were performed.

FIG. 10 is a schematic which represents ALD ZnO and conversion to chemical vapor deposition (CVD) MOF with around 10× volume expansion and gap fill.

FIGS. 11A-11C show AFM topography images of the CVD MOF films with starting ZnO seed layer thicknesses of (a) 2.5 nm, (b) 5 nm, and (c) 10 nm, respectively.

FIGS. 12A-12B are graphs showing (a) capacitance measurements for the MOF film with starting 5 nm ZnO layer in the frequency range 100 kHz-1 MHZ, and (b) corresponding I-V measurements.

FIG. 13 is a graph showing leakage current measured on 2 nm ALD Al₂O₃ coated MOF film; suppression of grain boundary leakage was observed.

FIGS. 14A-14B show the effect of ZnO growth temperature and CVD MOF conversion temperature on the MOF thickness, including cross-sectional SEM images of (a) ˜40 nm ZIF-8 film from ZnO seed layer thickness of 5 nm (ZnO grown at 120° C. and CVD MOF conversion performed at 120° C. for 120 min) and (b)˜130 nm ZIF-8 film from ZnO seed layer thickness of 25 nm (ZnO grown at 70° C. and CVD MOF conversion performed at 160° C. for 30 min).

FIGS. 15A-15E show a seamless high aspect ratio gap fill in a plasma free process.

FIG. 16 is a schematic of the MOF-CVD process.

FIGS. 17A-17C are cross-sectional SEM images of (a) MOF 120° C., (b) MOF 140° C. and (c) MOF 160° C. films on Si.

FIG. 18 is an image showing results of the MOF 160 C process.

FIG. 19A is a schematic illustration of the ZnO to ZIF-8 MOF conversion process, and FIG. 19B is a schematic which depicts the MOF gap fill mechanism as super fill.

### DETAILED DESCRIPTION OF EXAMPLE EMBODIMENTS

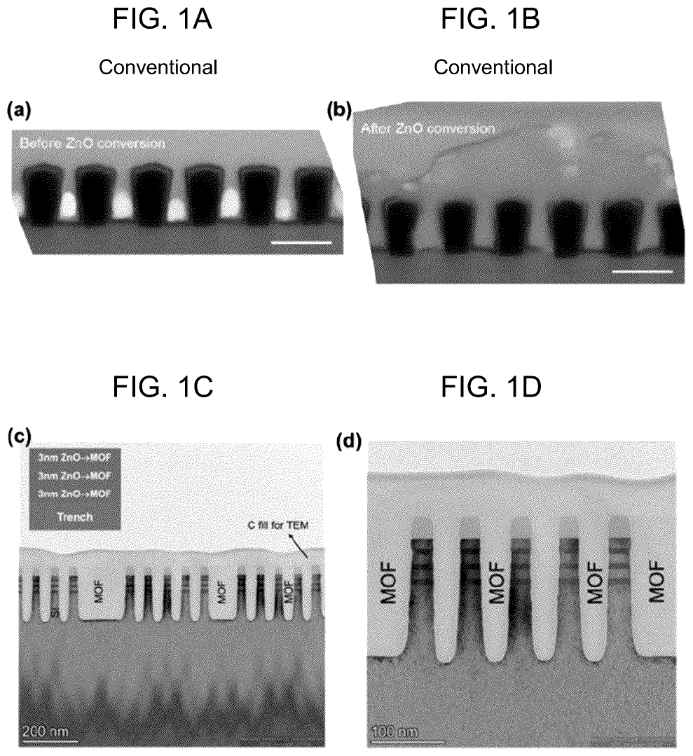

According to a recent study, using ALD of 6 nm ZnO followed by exposure to 2-methylimidazole vapor phase linker at CVD temperatures of 120° C. for 2 hours, modest MOF gap fill properties were shown with k as low as 2.2 and breakdown at 0.5 MV/cm. Although ZIF-8 MOF appears to be gap-filled in the 45 nm wide trenches, there is clear evidence of an unconverted or residual ZnO underlayer inside the trenches (see FIGS. 1A-1B), which looks to be a key limitation of their study. This could be attributed to the poor vacuum, 7.5 Torr used for their CVD MOF conversion apparatus. Their process time was also quite long, 2 hour for one MOF conversion cycle. In addition, the gap fill mechanism was not explained in the earlier literature.

In this context, as shown in FIGS. 1C-1D, the present disclosure shows rapid gap fill (15 min) with no residual ZnO. MOF conversion was done at 160 C; this process takes 15 min only for one conversion. The present process is about 8 times faster than all other reported processes due to the high processing temperature which was enabled by the better vacuum (˜900 mTorr) used in this disclosure (in embodiments of the present disclosure, the term “about” or the symbol “˜” means±10%). In one variation, nanolaminates structures were employed, i.e. the process of (converting from 3 nm ZnO to MOF) was repeated for 3 times (FIGS. 1C-1D): Low resolution image (FIG. 1C) showing 40 nm to 200 nm gaps were filled, high resolution image (FIG. 1D) showing no seam.

That is, FIGS. 1A-1D show TEM images of MOF gap fill processes from the literature vs. the present disclosure. In particular, FIGS. 1A-1B show the KU Leuven process. TEM measurements of lamellas taken from a capacitor device coated with 6 nm ALD ZnO before and after the CVD MOF conversion, scale bar is 100 nm, from the recent study. ZIF-8 MOF appears to be gap-filled in the 45 nm wide trenches; yet there is clear evidence of an unconverted or residual ZnO underlayer inside the trenches. This could be attributed to the poor vacuum, as 7.5 Torr was used for the CVD MOF conversion setup. Also, the process time was also quite long, 2 hour for one MOF conversion cycle. FIGS. 1C-1D show the process of the present disclosure. The present technique shows rapid gap fill with no residual ZnO. MOF conversion was done at 160 C, and this process takes for only 15 min for one conversion. The present process is about 8 times faster than other reported processes due to higher conversion temperature (160 C) enabled by better vacuum in the chamber for ZnO to ZIF-8 MOF conversion. For this experiment, 3 supercycles of MOF deposition were performed, i.e., the process of (converting from 3 nm ZnO to MOF) was repeated for 3 times. FIG. 1C is a low resolution image showing 40 nm to 200 nm gaps were filled. FIG. 1D is a high resolution image showing no seam. The yellow eye guided line shows the MOF boundary with the carbon fill used for TEM study.

High (ZnO to MOF) thickness expansion factor of ˜14× was also achieved in the present work, while only ˜4× expansion was reported in the previous work. The present breakdown field was ˜0.7 MV/cm, which is higher compared to 0.5 MV/cm previously reported. The present disclosure shows that only two parameters (i.e., ZnO seed layer thickness and CVD MOF conversion temperature) are the dominant variables for achieving defect free MOF with no residual ZnO.

Critical for high volume manufacturing, the MOF conversion time was reduced to only 15 min by raising the conversion temperature to 160° C., which was enabled by using better vacuum. It is possible higher temperature 165° C. to 175° C. might be enabled by even lower residual background gas during the ZnO to MOF conversion.

Fluorine plasma etch tests were also demonstrated for the first time for MOF 160 C vs. bare Si, SiCOH, and SiO₂. The etch rate was the following: SiCOH>Bare Si>SiO₂>MOF 160 C. MOF 160 C was the best to resist plasma etch.

Finally, both high aspect ratio gap fill and multiple aspect ratio gap fill was demonstrated; this is the first disclosure of multiple aspect ratio gap fill with no residual ZnO remaining. The MOF gap fill process was explained in detail, which could be ascribed as the capillary condensation (CC)—where the 2-methylimidazole precursor or 2-methylimidazole-ZnO reaction intermediates are adsorbed on the substrates as condensed liquid.

In the present disclosure, main benefits are (a) rapid thermal vapor phase process, (b) low k-value, (c) ability to seamless gap-fill narrow and wide features, and (d) plasma etch resistance. There are no known materials and/or processes that can fulfill (a) to (d) simultaneously for MOF or any other material.

While the primary application documented is for interconnect dielectric, MOF infill may also be used in thermal compression bonding for infill dielectric in chiplet-to-chiplet or chiplet-to-wafer bonding. At present, after copper bonding, the gap is filled by polymer or epoxy. The vapor phase MOF process would allow a small gap and tighter pitch Cu since it can fill extremely large aspect ratio features via a fast low-temperature reflow process described below. Gap infill in thermal compression bonding requires deposition in aspect ratios greater than 1000× since the gas must penetrate from the edge of the chiplet to the center. This requires just minor modifications of the ZnO ALD process, longer pulse and purge times.

MOFs can be synthesized using a gas-surface reaction involving an ALD-deposited metal oxide (for example, ZnO) and an organic linker to produce a structured material containing an open fraction as high as 70%, which can significantly reduce interconnect capacitance due to its low dielectric and reasonable mechanical strength.

In our previous work, MOF conversion was done at 120 C. Firstly, ZnO was deposited by ALD and subsequently, CVD MOF conversion was performed for 2 hours inside a vacuum oven (at 120° C. and pressure ˜900 mTorr) by keeping the ZnO film upside down in a sealed isothermal vessel with 2-methylimidazole powder present in excess. The objective of the present disclosure is to develop a faster MOF process so that it would be compatible with the microelectronics industry fabrication. The present disclosure shows CVD MOF conversion at two different temperatures, 140 C and 160 C. MOF 140 C conversion process took 1 hour. While raising the conversion temperature to 160 C, the process time was reduced to 15 min.

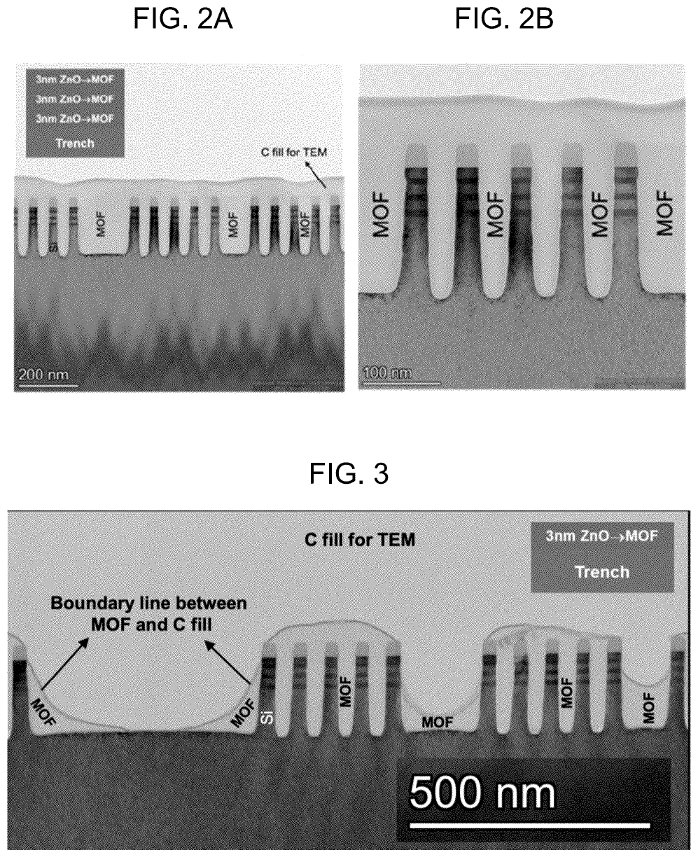

In this regard, FIGS. 2A-2B show 160 C as the optimal ZnO to ZIF-8 MOF conversion temperature. The present disclosure shows rapid gap fill with no residual ZnO. MOF conversion was done at 160 C, and this process takes for 15 min only for one conversion. The present process is about 8 times faster than other reported processes due to a higher ZnO to MOF conversion temperature enabled by better vacuum. As noted above, MOF deposition supercycles were used, i.e., the process of (converting from 3 nm ZnO to MOF) was repeated for 3 times. FIG. 2A is a low resolution image showing 40 nm to 200 nm gaps were filled. FIG. 2B is a high resolution image showing no seam. MOF films appeared to be self-planarizing, which is very good for the process. The yellow eye guided line shows the MOF boundary with the carbon fill used for TEM study.

That is, FIGS. 2A-2B show rapid gap fill with no residual ZnO. MOF conversion was done at 160 C, and this process takes 15 min only for one conversion. 160 C process is about 8 times faster than other report due to the better vacuum (˜900 mTorr) used in this disclosure. Here, nanolaminates structures were employed, i.e., the process of (converting from 3 nm ZnO to MOF) was repeated for 3 times. As noted above, a low resolution image shows 40 nm to 200 nm gaps were filled (FIG. 2A), and a high resolution image shows no seam (FIG. 2B). These kinds of nanolaminates structures (nanolaminates denote structure due to multiple MOF deposition supercycles) were used to achieve a thicker MOF film, which can be very crucial for microelectronic applications. As noted above, the MOF gap fill mechanism has been explained in detail and could be ascribed as the capillary condensation (CC)—where organic precursor or organic precursor-ZnO reaction intermediates are adsorbed into high aspect ratio features or the corners of larger features consistent with capillary condensation. In electroplating, a similar process is called superfill. This process results in the smaller features filling first and the larger features filling for the corners first. The process may rely on the reaction of the ZnO film with the organic vapor (imidazole) being in an isothermal reactor with the organic vapor at saturated vapor pressure. This was achieved by having the organic source in the same vacuum chamber as the substrate for the ZnO to MOF conversion. Note even when too thin a MOF is formed to fill the wider features, no residual ZnO is observed in the center of the wide features (see FIG. 3, discussed further below).

FIG. 3 shows that the MOF 160 C process results in the smaller features filling first and the larger features filling for the corners first. Note even when too thin a MOF is formed to fill the wider features, no residual ZnO is observed in the center of the wide features. For this experiment, 1 supercycle of MOF deposition was performed, i.e., the process of (converting from 3 nm ZnO to MOF) was done one time.

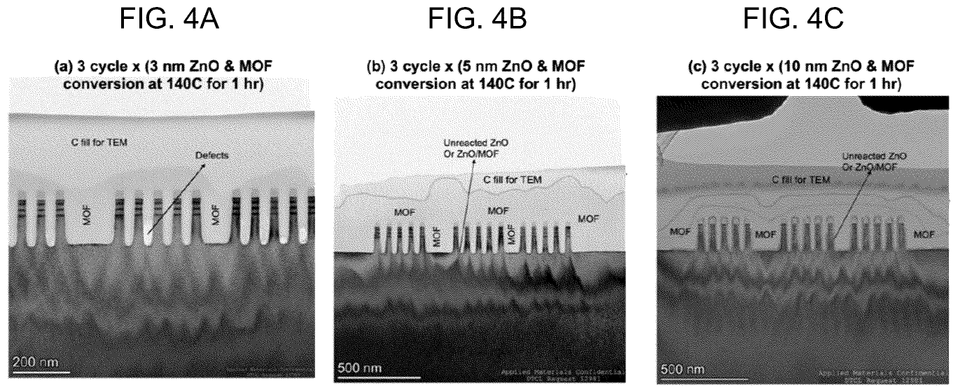

In contrast, FIGS. 4A-4C show the failure of MOF 140 C as gap fill. The 140 C process showed defects with 3 nm ZnO (a) 3 supercycles with 3 nm MOF and conversion at 140 C: the yellow eye guided line shows the MOF boundary with the carbon fill used for TEM study (see FIG. 4A); (b) 3 supercycles with 5 nm MOF and conversion at 140 C: there was excess or unreacted ZnO, which is not good for the process (see FIG. 4B); and (c) 3 supercycles with 5 nm MOF and conversion at 140 C: there was excess or unreacted ZnO, which is not good for the process (see FIG. 4C). Note 10 nm ZnO, its filling of the narrow features first is consistent with capillary condensation. The MOF gap fill in indicated by two eye guided lines, showing MOF process cycle by cycle.

FIGS. 4A-4C show the study on the MOF gap fill done at 140 C. The process showed defects with 3 nm ZnO (FIG. 4A), the yellow eye guided line shows the MOF boundary with the carbon fill used for TEM study. With 5 and 10 nm ZnO, there was excess or unreacted ZnO (FIGS. 4B-4C), which is not good for the process. Note 10 nm ZnO, its filling of the narrow features first is evident as capillary condensation (FIG. 4C); the MOF gap fill is indicated by two eye guided lines, showing MOF process cycle by cycle. This study showed a clear pathway that mainly two parameters (i.e., ZnO seed layer thickness and CVD MOF conversion temperature) played the major role for defect free MOF with no residual ZnO. Therefore, the MOF 160 C process turns out be optimal for gap fill.

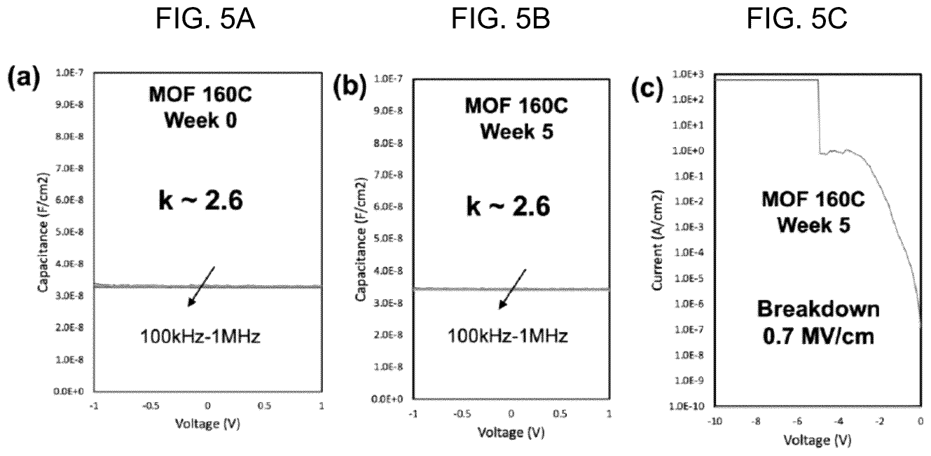

FIGS. 5A-5C show the k value, breakdown, and air stability for MOF 160° C. film. In particular, FIG. 5A shows C-V plots for the MOF 160 C film (˜70 nm MOF thickness) in the frequency range 100 kHz-1 MHZ, measured at week 0, FIG. 5B shows the same device re-measured after week 5, and FIG. 5C shows I-V measurements of the same device after week 5.

In greater detail, parallel plate capacitors were fabricated, and the same device was measured at week 0 and after week 5. The k-value of the MOF layer was extracted from the capacitance data measured at frequencies in the range 100 kHZ-1 MHZ (FIGS. 5A-5B). The k-value was estimated to be ˜2.6, which is consistent with the previous results obtained in the literature. The C-V data clearly shows the MOF is very much stable in ambient air over months. Additionally, I-V measurements (FIG. 5C) were also performed to examine the leakage and breakdown in the films, and it was found that leakage was very minimal. Breakdown was seen at ˜0.7 MV/cm, which is higher compared to 0.5 MV/cm reported previously. This is consistent with zero residual ZnO in the films as well as possible improved grain structure from high temperature process with lower background H₂O.

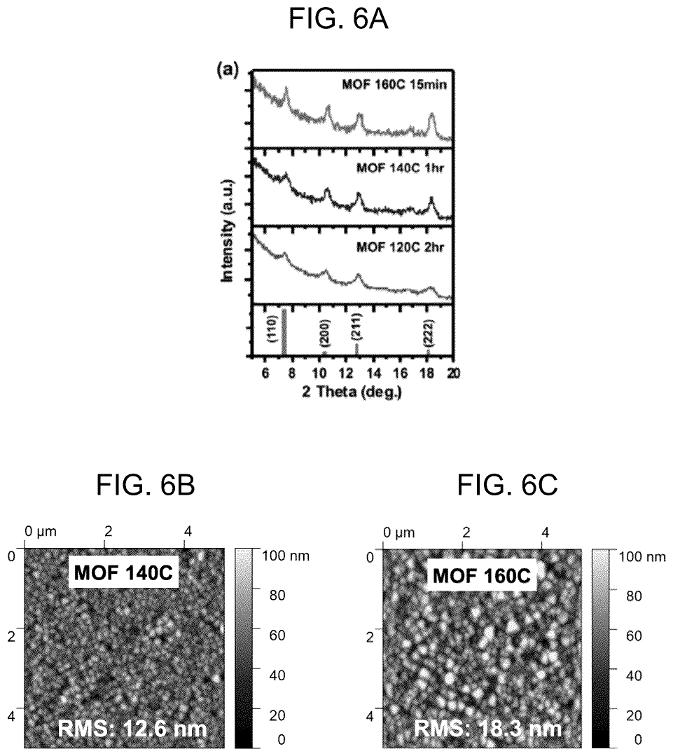

FIGS. 6A-6C show the structure and morphology of MOF 160 C, and comparison with that of 120 C and 140 C. In particular, FIG. 6A shows the grazing incidence X-ray diffraction (GIXRD) pattern of MOF 120 C, 140 C and 160 C films and reference ZIF-8 MOF JCPDS data. FIGS. 6B and 6C show AFM topography images of the CVD MOF films at 140 C and 160 C, respectively. All the AFM images are taken in 5 μm×5 μm scale.

In greater detail, the crystalline structure of the MOF films was examined by GIXRD (see FIG. 6A). It can be seen from FIG. 6A that with the increase of the MOF conversion temperature from 120 C to 160 C, the XRD peaks became more intense and FWHM (full width half maximum) of all the peaks were decreased. This indicates MOF 160° C. film is more crystalline than that of 120 C and 140 C. In addition, the AFM topography images (FIGS. 6B-6C) also demonstrated much bigger MOF grains for 160 C sample, although RMS of 160 C was found to be increased. Therefore, chemical mechanical polishing (CMP) is proposed to be done to reduce the RMS for some applications.

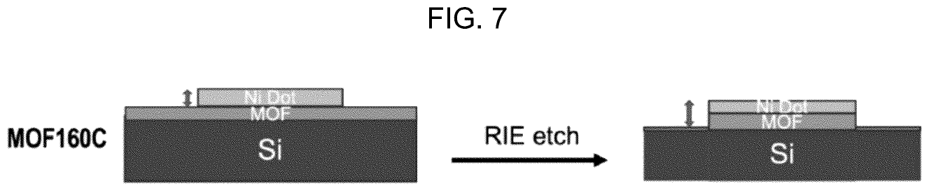

FIG. 7 shows a schematic of a CHF₃ plasma etch test for MOF 160 C. In particular, a CHF₃ plasma etch test (fluorine plasma etch) was also demonstrated for the first time for MOF 160 C vs. bare Si, SiCOH, and SiO₂. The etch conditions were the following: Power: 150 W, Time: 20 s, Pressure: 30 mTorr (25 sccm Ar+25 sccm CHF₃) at room temperature. As noted above, FIG. 7 shows the schematic of the etch test for MOF 160 C. Before and after etch, Ni dots heights were measured from Dektak images. So, from the height difference, the etch rate (nm/min) was calculated, which is summarized in Table 1 below. The etch rate (nm/min) was the following: SiCOH>Bare Si>SiO₂>MOF 160 C. MOF 160° C. was the best to resist plasma etch in this series.

TABLE 1
Etch test results for MOF 160 C. and comparison
with bare Si, SiCOH, and SiO₂

| | Before etch | After etch | | |
|---|---|---|---|---|
| | Ni dot | Ni dot | Δ Height | Etch rate |
| Samples | height (nm) | height (nm) | (nm) | (nm/min) |
| Bare Si | 67.32 | 89.22 | 21.9 | 65.8 |
| MOF 160 C. | 87.07 | 95.8 | 8.73 | 26.2 |
| SiCOH | 81.71 | 129.38 | 47.67 | 143.2 |
| SiO₂ | 79.45 | 92.31 | 12.86 | 38.6 |

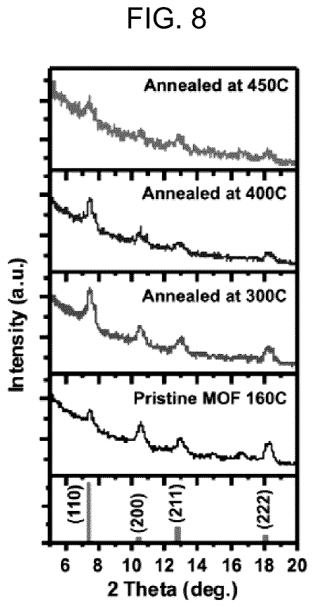

FIG. 8 shows a thermal stability test of MOF 160 C. The film was annealed first at 300 C (for 30 min at 1E-2 Torr), then at 400 C (for 30 min at 1E-2 Torr), and finally at 450 C for 15 min at 1E-6 Torr. After each annealing, GIXRD was measured.

The thermal stability for the MOF 160 C was checked (FIG. 8). The annealing study was done at three different temperatures, 300 C, 400 C, and 450 C, and after each annealing step, GIXRD was measured to check whether the MOF was stable or not. The MOF 160 C film was annealed first at 300 C (for 30 min at 1E-2 Torr), then at 400 C (for 30 min at 1E-2 Torr), and finally at 450 C for 15 min at 1E-6 Torr. MOF was thermally stable up to 450 C, although there is a small decrease in the crystallinity at 450 C. This could be attributed to the presence of water in the environment which could react with the MOF and further decompose it at this high temperature. Previous literatures also showed thermal stability of ZIF-8 MOF up to 500 C for about 1 hour in N2 atmosphere. The thermal stability of MOF up to 450 C demonstrates that it can be used in BEOL, FEOL device fabrication, packaging, and 3D heterogeneous integration (3DHI).

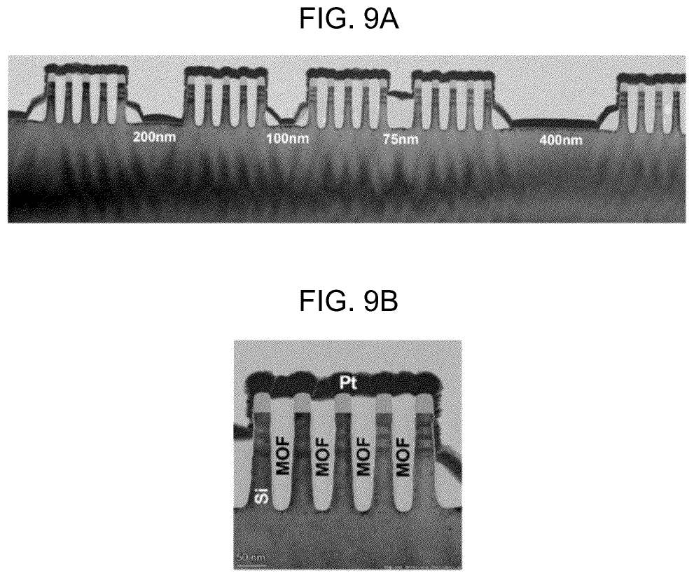

FIGS. 9A-9B show another embodiment of the present disclosure, in which 1 nm ALD ZnO and then conversion to MOF were performed. In particular, FIG. 9A is a low resolution image showing 40 nm to 400 nm gaps were filled, and FIG. 9B is a high resolution image showing no seam.

In this context, as shown in the illustrative embodiment of FIGS. 9A-9B, some embodiments of the present disclosure show, or substantially complete, ZnO to MOF conversion with ultralow-k dielectrics (k value ˜2.2) for seamless thin gap-fill dielectrics in the 40 nm, 75 nm, 100 nm, and 200 nm wide trenches for semi-damascene. Also, higher (ZnO to MOF) thickness expansion factor of ˜8 may be obtained in some embodiments. Besides, breakdown may be seen for some embodiments at ˜1 MV/cm which is higher compared to 0.5 MV/cm in other embodiments. Furthermore, nanolaminates structure may be employed to produce the thicker MOF films. Additionally, the present disclosure demonstrated a new way that, depending upon the quality of the ZnO seed layer and CVD MOF conversion temperature, a thicker MOF may be achieved in one single cycle. In some embodiments, lower temperature (e.g., 70° C.) grown ZnO can be amorphous which can allow the 2-methylimidazole linker to penetrate more into the ZnO matrix and produce more thicker MOF. These results show that in some embodiments, two parameters (i.e., ZnO growth temperature and CVD MOF conversion temperature) may play a major role for achieving thicker MOF which is very crucial for RF. Also, in some embodiments, the CVD MOF conversion time can be significantly reduced to only 30 minutes by raising the conversion temperature to 160° C.

Finally, a reason behind the MOF gap fill processing some embodiments could be ascribed as the capillary condensation (CC)—where MOF vapors are adsorbed into porous avenues via multilayer mechanism which results in a condensed liquid.

In the some embodiments, main benefits may include (a) a low k-value, (b) high mechanical strength (such as high Young's modulus and fracture resistance), and (c) an ability to gap-fill narrow and wide features. There are no known materials in the industry that can fulfill (a) to (c) simultaneously.

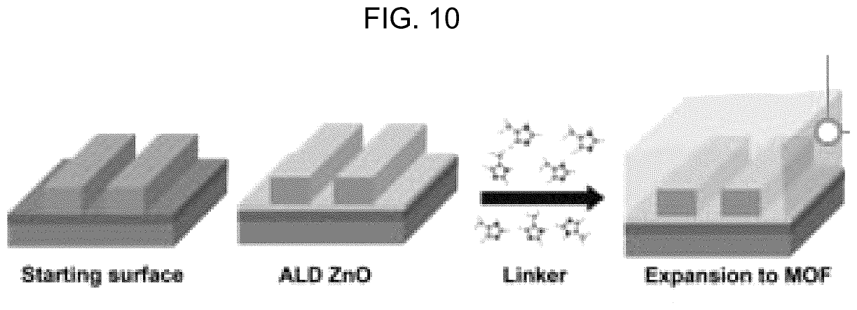

As schematically presented in FIG. 10, MOFs can be synthesized using a gas-surface reaction involving an ALD-deposited metal oxide and an organic linker to produce a structured material containing an open fraction as high as 70%, which can significantly reduce interconnect capacitance due to its low dielectric and reasonable mechanical strength.

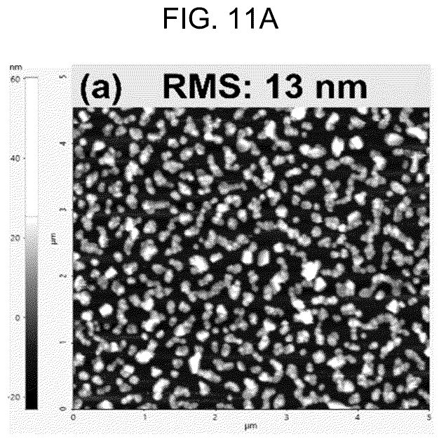

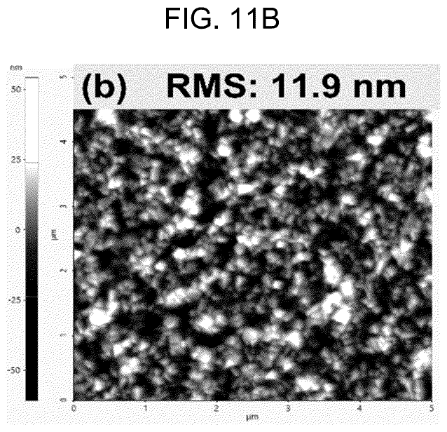

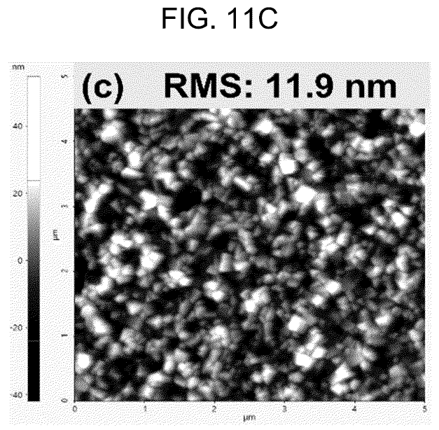

In some embodiments, as the initial step, ZnO was deposited by ALD at process temperature 120° C. Subsequently, the MOF conversion was performed inside a vacuum oven (at 120° C. and pressure ˜1 Torr) by keeping the ZnO film upside down in a sealed isothermal vessel with 2-methylimidazole powder present in excess. The surface topography of the as-grown MOF films was studied using AFM vs. starting ZnO seed layer thickness. It was determined that at 120° C. the maximum thickness of ZnO which could be fully converted in one cycle was around 5 nm. FIGS. 11A-11C show AFM topography images of the CVD MOF films with starting ZnO seed layer thicknesses of (a) 2.5 nm, (b) 5 nm, and (c) 10 nm, respectively. All the AFM images are taken in 5 μm×5 μm scale. As shown in FIG. 11A, when 2.5 nm ZnO was converted, the film was not conformal and having pinholes. Conversely, as shown in FIG. 11B, if 5 nm ZnO film was employed, the film was conformal with no pinholes and relatively smoother surface. This 5 nm ZnO was converted to about 40 nm of MOF (measured from cross-sectional SEM). With an increase the ZnO seed layer thickness to 10 nm (FIG. 11C), there was some excess ZnO at the bottom of the film not converting to the MOF. Therefore, in one cycle, 5 nm ZnO as starting layer was found to be optimum and was fully converted to MOF for planar samples. However, as shown below the ZnO thickness limitation is different in narrow gaps since the MOF acts as a diffusion barrier.

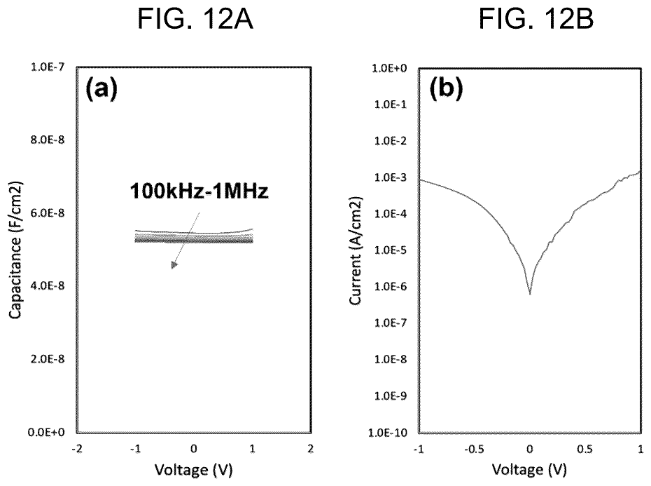

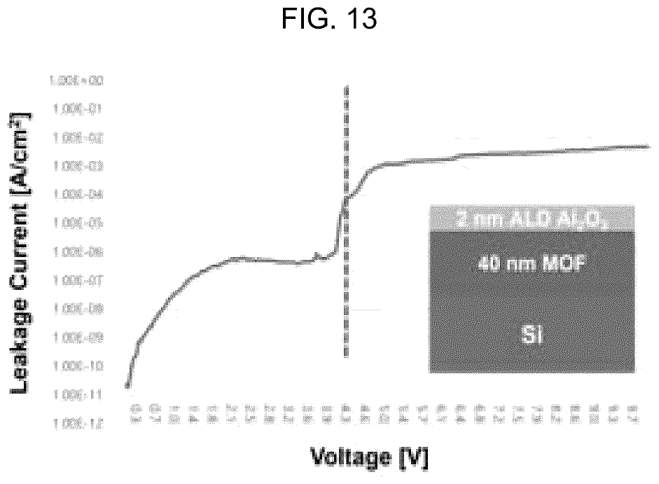

In some embodiments, parallel plate capacitors may be fabricated, and the k-value of the MOF layer may be extracted from the capacitance data measured at frequencies in the range 100 kHZ-1 MHZ (FIG. 12A). The k-value for these embodiments was estimated to be 2.2 which is consistent with the results obtained earlier in some embodiments. Additionally, I-V measurements (FIG. 12B) may be also performed to examine the leakage in the films, and it was found that in some embodiments leakage was insignificant. To further reduce the leakage current for some embodiments, nanolaminates may be fabricated, where an illustrative example of a nanolaminate consisted of 40 nm of MOF and 1-2 nm of ALD Al₂O₃. As shown in FIG. 13, in some embodiments, a single layer of 2 nm Al₂O₃ can reduce the leakage dramatically in the MOF films to the detection limit. This can be attributed to the Al₂O₃ which may in some embodiments block the grain boundary leakage. Breakdown in some embodiments may be seen at ˜1 MV/cm which is higher compared to 0.5 MV/cm seen in some embodiments.

As thicker MOF (in the range of 100 nm or more) may be crucial for RF, in the present disclosure, nanolaminates structures may be further employed to produce the thicker MOF films.

Using nanolaminates, the step (ALD ZnO and converted to MOF) may be repeated until the desired MOF thickness was achieved. Also, in some embodiments, depending upon the quality of the ZnO seed layer and CVD MOF conversion temperature, the thicker MOF can be achieved in one single cycle.

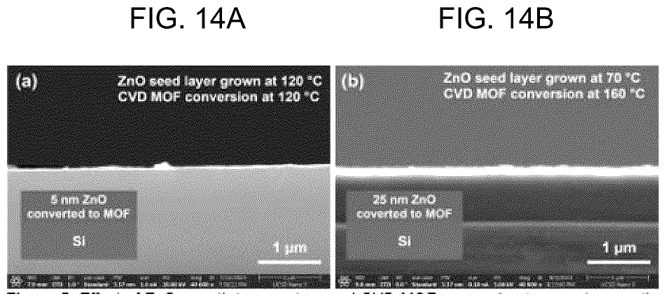

As shown in FIG. 14A, with 5 nm ZnO seed layer grown at 120° C., and using CVD MOF conversion temperature of 120° C., the conversion produced ˜40 nm ZIF-8. The conversion time may be in some embodiments 120 min. Conversely, as can be seen from FIG. 14B, with 25 nm ZnO seed layer grown at lower ALD temperature, 70° C. and using a higher CVD MOF conversion temperature of 160° C., the conversion produced ˜130 nm ZIF-8. And the conversion time may be reduced significantly to 30 min for some embodiments. It could be attributed to the lower temperature grown ZnO can be amorphous which allows the 2-methylimidazole linker to penetrate more into the ZnO matrix and produce a thicker MOF. These results showed a path for some embodiments that two parameters (i.e., ZnO growth temperature and CVD MOF conversion temperature) played a major role to achieve thicker MOF in one single cycle which can be crucial for RF.

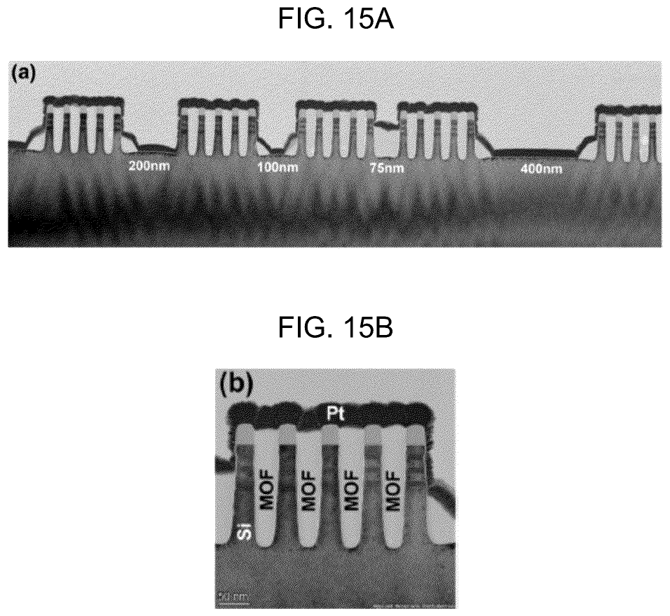

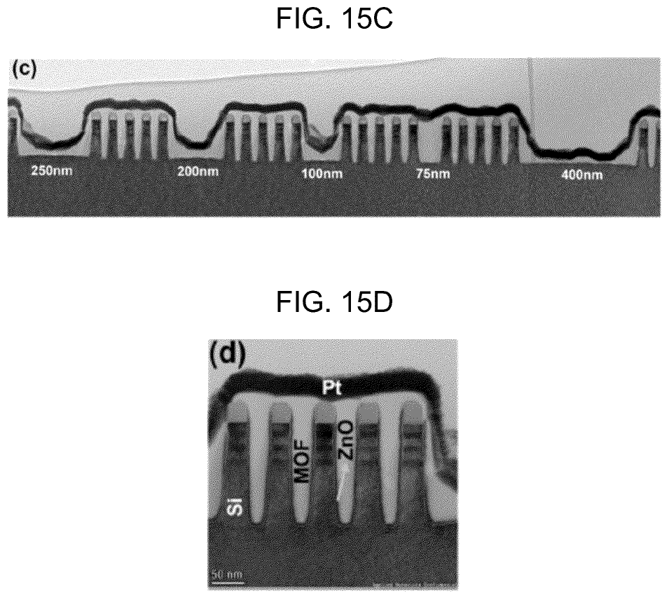

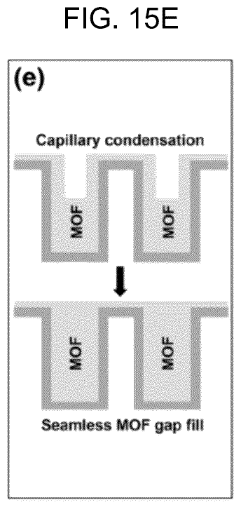

FIGS. 15A-15E show a seamless high aspect ratio gap fill in a plasma free process. The gap width ranges from 40 nm to 400 nm. In regard to FIGS. 15A-15B, 1 nm ALD ZnO and then conversion to MOF were performed: (a) a low resolution image shows 40 nm to 400 nm gaps were filled, and (b) a high resolution image shows no seam. As to FIGS. 15C-15D, 3 nm ALD ZnO and conversion to MOF were performed, and a residual film of ZnO remains due to MOF acting as a linker diffusion barrier. FIG. 15E is a schematic showing seamless MOF gap fill via capillary condensation.

In particular, gap fill was further studied using patterned samples with gaps from 40 nm to 400 nm. 1 nm of ALD ZnO was deposited and then converted to the MOF. As shown in FIGS. 15A-15B, seamless gap fill was observed in the 40 nm, 75 nm, 100 nm, and 200 nm wide trenches. As shown in FIGS. 15C-15D, for 3 nm ZnO to MOF conversion, a residual film of ZnO remains due to MOF acting as a linker diffusion barrier. As represented in FIG. 15E, this gap fill process could be ascribed as the capillary condensation (CC)—where MOF vapors are adsorbed into porous avenues via multilayer mechanism which results in a condensed liquid. The surface is rough, but this can be fixed using a polishing step. This process has potential as a plasma-free vapor phase seamless gap fill for high aspect ratio features.

Various exemplary embodiments of this aspect of the present disclosure are set forth below.

1. ALD ZnO growth optimization
Growth optimization of ALD ZnO was conducted on Si substrates.
The pulse length of the precursor, substrate temperature, and purge gas flow rate were controlled and optimized.

2. ZnO to ZIF-8 MOF conversion & ZIF-8 as ultra-low-k dielectrics
MOF conversion was performed inside a vacuum oven by keeping the ZnO film upside down in a sealed isothermal vessel with 2-methylimidazole powder present.
The surface topography of the MOF films was studied using AFM and MOF film thickness was measured using cross-sectional SEM.
Ultra-low-k value of around 2.2 was achieved.

3. Nanolaminates structure to produce the thicker MOF
Nanolaminates structure were used to produce the thicker MOF films.
The step (ALD ZnO and converted to MOF) was repeated until the desired MOF thickness was achieved.

4. Al₂O₃ coating to reduce the leakage and enhance the breakdown
A single layer of 1-2 nm of ALD Al₂O₃ can reduce the leakage dramatically in the MOF films to the detection limit.
This was due to the Al₂O₃ layer was blocking the grain boundary leakage and further increase the breakdown.

5. Two important parameters: ZnO growth temperature and CVD MOF conversion temperature
Two parameters (i.e., ZnO growth temperature and CVD MOF conversion temperature) played the major role to achieve thicker MOF in one single cycle which is very crucial for RF. This shows a new way to achieve the best ZIF-8 MOF playing with these two parameters.

6. MOF films as seamless high aspect ratio gap fill
Gap fill was studied using patterned samples with gaps from 40 nm to 400 nm.
The gap fill mechanism was explained and it could be ascribed as the capillary condensation (CC)—where MOF vapors are adsorbed into porous avenues via multilayer mechanism which results in a condensed liquid.

The present disclosure provides ZIF-8, wherein ZIF-8 is (C₈H₁₂N₄)Zn. This structure is unique and has a regular lattice pattern where Zn is sole metal atom and is in the center of the repeating unit. Properties include a dielectric constant below 3 and above 2, a Young's modulus comparable to the Young's modulus of porous organosilanes with a comparable K value, and thermal stability up to 500 C.

The present disclosure also provides a process for preparing a laminate, comprising: (1) atomic layer deposition (ALD) of zinc oxide as a base between 1 nm to 10 nm in thickness, (2) exposing 2-methylimidazole vapor phase linker at chemical vapor deposition at a temperature range of greater than 140 C to 180 C in a vacuum condition (avoids water and oxygen), and (3) cycling of the ZnO ALD and 2-methylimidazole exposure to deposit a film or fill a gap. In one embodiment of the present disclosure, a thickness of the zinc oxide base is 5 nm, which results in a MOF film that is conformal with no pinholes and a relatively smooth surface. In embodiments of the present disclosure, a preferred temperature range can be greater than or equal to 145 C and less than or equal to 180 C, a more preferred temperature range can be greater than or equal to 150 C and less than or equal to 180 C, a particularly preferred temperature range can be greater than or equal to 160 C and less than or equal to 180 C, and a particularly preferred temperature is 160 C. In one embodiment of the present disclosure, the cycling is conducted such that the combination of the ALD and exposure processes is carried out three times. The thickness of the zinc oxide base may be up to 5 nm. In one aspect of such an embodiment, the thickness of the zinc oxide base may be 3 nm. In another aspect of such an embodiment, the thickness of the zinc oxide base may be 5 nm. The cycling is conducted as many times as is needed to achieve the desired thickness of the laminate, which can be, e.g., up to 200 nm or even up to 300 nm.

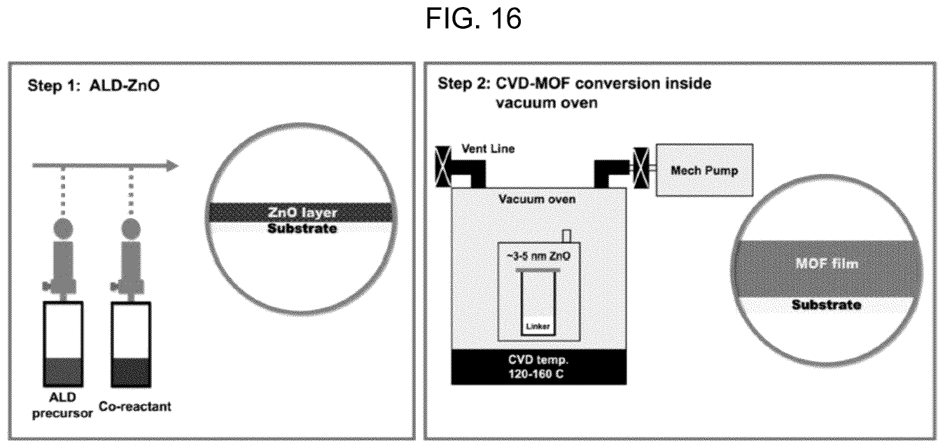

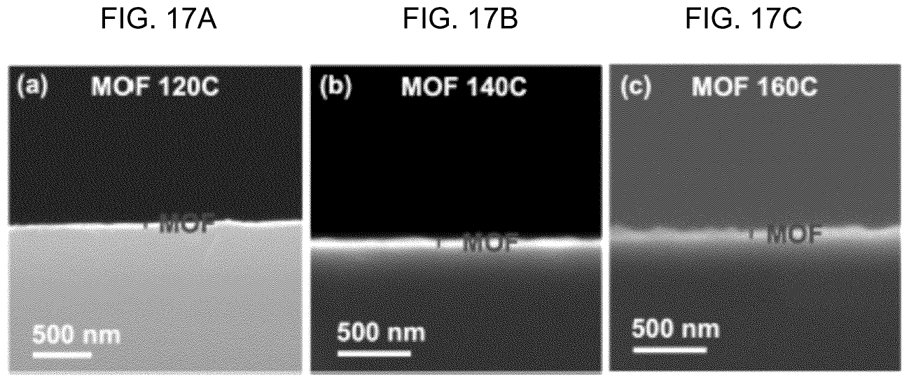

For instance, as shown in FIG. 16, the process is divided into two steps: the first is the metal oxide deposition by ALD, and the second is the vapor-solid reaction to form the MOF. Step (1) is ALD of ZnO: Zn(C2H5)2(g)+H2O(g)→ZnO(s)+2 C2H6(g), and then step (2) is vapor exposure of the organic linker, 2-methylimidazole, which initiates the vapor-solid reaction forming the MOF by CVD: ZnO(s)+2HmIM(g)→H2O(g)+ZIF-8(s). As the initial step, ZnO was deposited by ALD and subsequently, the MOF-CVD conversion was performed inside a vacuum oven (varying CVD temperatures between, e.g., 120-160° C. and pressure ˜750 mTorr) by keeping the ZnO film upside down in a sealed isothermal vessel with 2-methylimidazole powder present in excess. FIGS. 17A-17C show cross-sectional SEM images of (a) MOF 120° C., (b) MOF 140° C. and (c) MOF 160° C. films on Si. Starting from 5 nm ALD ZnO on top of an Si substrate, the MOF conversion resulted in ˜45 nm, ˜60 nm and ˜70 nm ZIF-8 MOF films for 120 C, 140 C, and 160 C, respectively. The thickness expansion factor from ZnO to MOF was found to be 9, 12, and 14, for MOF 120 C, 140 C and 160 C respectively.

As an example of MOF-CVD Process Step 1, ALD ZnO on a blanket wafer was carried out as follows. Highly doped p⁺⁺Si substrates were pre-cleaned by immersion in Piranha solution (3:1 H₂SO₄:H₂O₂) for 10 minutes, then immersion in de-ionized (DI) water for 5 minutes, and finally drying in nitrogen (N2, 99.999% purity). ZnO films were deposited on Si substrates in a custom-built ALD reactor with diethylzinc (DEZ, 97%, Strem Chemicals) as the precursor and deionized water as the co-reactant. One ALD reaction cycle consisted of a 0.25 s exposure to DEZ, followed by a 20 s vacuum purge, a 0.25 s exposure to H₂O, and then another 20 s vacuum purge. The reactor base pressure was maintained at 400 mTorr. This process resulted in a ZnO growth rate of ˜2 Å/cycle on Si substrates at 120° C. As another example, ALD ZnO deposition on patterned wafers was achieved by employing the same growth conditions as used on blanket wafers as described above.

As an example of MOF-CVD Process Step 2, vapor-phase MOF conversion was carried out as follows. MOF-CVD conversion was performed inside a vacuum oven (varying CVD temperatures between 120-160° C. and pressure ˜750 mTorr) by keeping the ZnO film upside down in a sealed isothermal vessel with 2-methylimidazole powder present in excess. Initially, MOF conversion was done at 120° C., and this process took 2 hours for one conversion cycle and these samples are referred as MOF 120 C. Afterward, MOF conversion temperature was increased to 140° C. and by doing that the process cycle time was reduced to 1 hour; and these samples are referred as MOF 140° C. Finally, the MOF conversion temperature was raised to 160° C. and the process time was significantly reduced to 15 minutes only. These samples are referred as MOF 160 C. To form thicker MOF films, nanolaminates structures were employed, i.e., the process of (converting from 3 nm or 5 nm ZnO to MOF) was repeated for 3 times.

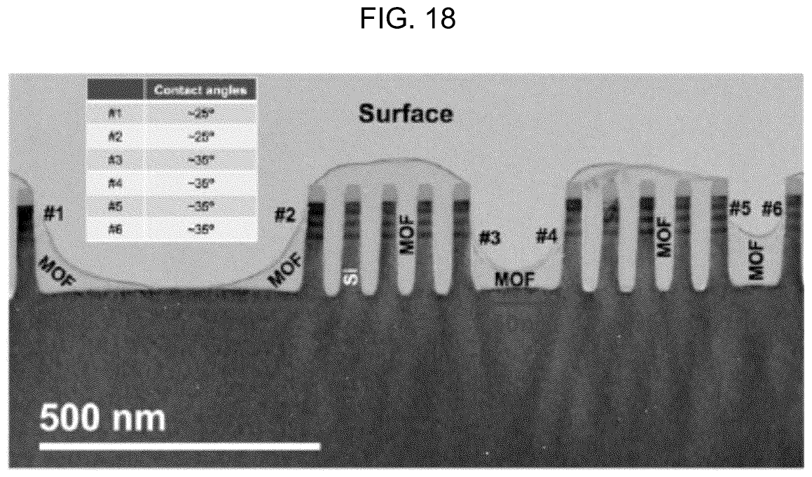

FIG. 18 shows that the MOF 160 C process results in the smaller features filling first and the larger features filling for the corners first. When too thin a MOF is formed to fill the wider features, no residual ZnO is observed in the center of the wide features nor at the top edges of the medium size features. For this experiment, 1 supercycle of MOF deposition was performed, i.e., the process of (converting from 3 nm ZnO to MOF) was done for 1 time. As shown FIG. 18, even when too thin a MOF is formed to fill the wider features, no residual ZnO is observed in the center of the wide features nor at the top edges of the medium size features. It is noted that the narrower trenches have high fill factors compared to the wide trenches.

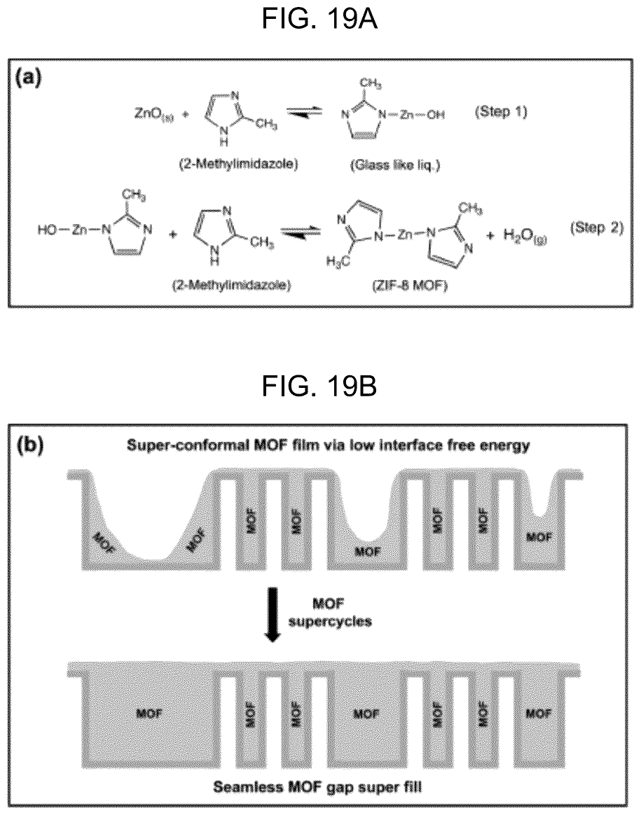

Before explaining the MOF gap fill mechanism, ZnO to ZIF-8 MOF conversion process is schematically explained in FIG. 19A. The ZnO to ZIF-8 MOF transformation under vapor phase transport conditions should occur at the interface between 2-methylimidazole vapor and ZnO. A possible explanation for the ZnO to ZIF-8 conversion is that a hydroxylated intermediate in an amorphous glass-like state can undergo reflow.

The MOF gap fill mechanism is explained in detail in FIG. 19B; it is hypothesized that the MOF fills the trenches by low interfacial free energy—where an organic precursor-ZnO reaction intermediates are selectively adsorbed into high aspect ratio features or the corners of larger features consistent. There is one interesting thing to be noted that no MOF is on the side wall and bottom of the trenches. This supports the MOF gap fill mechanism via low interface free energy compared to the surface free energy. In electroplating, a similar process is called superfill. This process results in the smaller features filling first and the larger features filling for the corners first. The process may rely on the reaction of the ZnO film with the organic vapor (imidazole) being in an isothermal reactor with the organic vapor at saturated vapor pressure. This was achieved by having the organic source in the same vacuum chamber as the substrate for the ZnO to MOF conversion.

Embodiments of the present disclosure avoid the trade-off between low-k value and strong mechanical strength that is observed in SiCOH materials (POR). MOF will have low-k value, strong mechanical strength, and also a different etch behavior (more resistant to etch damage). An unexpected benefit seen in experimentation is that MOF can gap-fill very high aspect ratio structures.

An embodiment of the present disclosure involves engineering of the ALD ZnO composition (not just thickness). It is thought that higher Zn content can be beneficial (compared to the stoichiometric 1:1 ratio of Zn and O amount in the film). This can be achieved by keeping the ZnO ALD temperature low (below 200 C) and/or controlling the precursor flows. Having a Zn-rich ZnO film may help improve nucleation of the MOF film in the subsequent step.

Another embodiment of the present disclosure involves engineering the initial ZnO film, e.g., by introducing Al in the ALD process, using TMA or TEA or equivalent Al precursor, to create an “AZO” or Aluminum Zinc Oxide film, with Al content of <10%. The goal is (a) improve adhesion, (b) improve leakage of MOF film since the small amount of Al-O species on the surface will remain and block electrical current that can get through grain boundaries or pinholes in the MOF, and (c) improve quality of the low temperature ZnO or AZO film (density, continuity, etc.) for MOF synthesis.

In another embodiment of the present disclosure, a thin or “flash” PVD film of Ti, at <1 nm thickness, can be added before the ZnO ALD, with the same goals as in the preceding paragraph. This will then oxidize into a very thin layer of TiOx in the MOF synthesis.

Yet another embodiment to enable gapfill of MOF: start with ZnO either at the bottom of the features or at the bottom and sidewalls of the features only, instead of starting with a conformal layer of ZnO everywhere.

In a preferred embodiment of the present disclosure, the gas surface reaction is conducted at a pressure of less than or equal to about 1 mTorr, facilitated by a turbo vacuum pump with a pumping capacity in liters per second (L/s) ranging from 50 L/s to 1000 L/s.

In conclusion in regard to an aspect of the present disclosure, various embodiments of the present method successfully demonstrated CVD MOF films as seamless high aspect ratio gap fill ultra-low-k dielectrics for applications in logic and gap fill mechanism as has been explained in detail. In logic, there is an urgent demand for lower k dielectrics (interlayer dielectrics, ILD) with the required thermal, electrical, and mechanical properties to be replaced into M1 and M2. This CVD ZIF-8 MOF film with ultra-low-k dielectrics has the potential as a plasma-free vapor phase seamless gap fill for high aspect ratio features to be applied in logic. Therefore, applications can include BEOL, and also applications in FEOL device fabrication, packaging, and 3DHI.

Further, the present disclosure includes the following:

1. ALD ZnO growth optimization
ALD ZnO growth was optimized on Si substrates.
The precursor's pulse length, substrate temperature, and purge gas flow rate were all controlled and tuned.

2. CVD MOF at 140 C and 160 C
CVD MOF conversion was tested at two different temperatures, 140 C and 160 C, inside a vacuum oven, with the ZnO film upside down in a sealed isothermal container containing 2-methylimidazole powder.
The 160 C process turned out to be a rapid process (15 min only) vs. 140 C process (1 hour).
Structure and morphology of the MOF films were measured.
K-value, breakdown, and air stability were checked.

3. Nanolaminates structure to produce the thicker MOF
Nanolaminates structure were employed to generate the thicker MOF films.
The process of (converting from ZnO to MOF) was repeated until the required MOF thickness was obtained.

4. MOF films as seamless high aspect ratio gap fill
Gap fill was studied using trench samples with gaps from 40 nm to 400 nm.
MOF 160 C process produced seamless best gap fill over MOF 140 C.
It was also found out that ZnO seed layer thickness also played a significant role to remove any residual ZnO from the MOF and 3 nm ZnO was the best thickness to start with.

5. Thermal stability and plasma etch test of MOF
Thermal stability of MOF 160 C was checked.
MOF 160 C was stable up to 450 C in vacuum (1E-6 Torr).
Plasma etch test was done for MOF 160 C vs. bare Si, SiCOH, and SiO₂.
Etch rate: SiCOH>Bare Si>SiO₂>MOF 160 C. MOF 160 C was the best to resist etch.

Applications of the present disclosure can be found in BEOL, FEOL device fabrication, packaging, and three-dimensional heterogeneous integration (3DHI).

In logic and memory device fabrication, lower k dielectrics (also known as interlayer dielectrics, ILD) with the necessary thermal, electrical, and mechanical properties are needed to isolate metal conductors (lines and vias). The requirements for ILD are stringent, including high thermal stability, electrically insulating, low dielectric constant, high mechanical strength, etc. ILD materials used in the subtractive BEOL applications (where metal conductors are patterned and etched, and ILD is then deposited in the etched regions) must also enable gap-fill (filling the etched regions without voids). This disclosure demonstrated that CVD ZIF-8 MOF film with low-k dielectrics has the potential to be a plasma-free vapor phase seamless gap fill for high aspect ratio features to be employed in logic and memory device fabrication.

Other applications in logic and memory device fabrication include the use of the MOF film as an etch-stop to be placed under other materials, since the MOF has etch selectivity compared to films such as SiCOH and Si. As an etch-stop, MOF can protect the underlying substrate from being damaged or removed, during the etch process of the material above the MOF. MOF can also be used as a second patterning “color” in logic fabrication schemes, since it has etch selectivity compared to other dielectrics such as SiCOH.

While the primary application documented is for interconnect dielectric, MOF infill may also be used in thermal compression bonding for infill dielectric in chiplet-to-chiplet or chiplet-to-wafer bonding. At present, after copper bonding, the gap is filled by polymer or epoxy. The vapor phase MOF process would allow a small gap and tighter pitch Cu since it can fill extremely large aspect ratio features via a fast low-temperature reflow process. Gap infill in thermal compression bonding requires deposition in aspect ratios greater than 1000× since the gas must penetrate from the edge of the chiplet to the center. This requires just minor modifications of the ZnO ALD process, longer pulse and purge times.

The foregoing is illustrative of exemplary embodiments and is not to be construed as limiting the disclosure. Although a few exemplary embodiments have been described, those skilled in the art will readily appreciate that many modifications are possible in the above embodiments without materially departing from the disclosure.

What is claimed is:

1. A process for forming a vapor-deposited ZIF-8 metal organic framework, referred to as ALD-ZnO+soak cycle, comprising:
conducting a gas surface reaction between an ALD-deposited ZnO and 2-methylimidazole to form a vapor-deposited ZIF-8 metal organic framework;
wherein the gas surface reaction is conducted at a temperature greater than 140 C, and
wherein the gas surface reaction is conducted at a pressure of less than 1000 mTorr.

2. The process according to claim 1, wherein the gas surface reaction is conducted at a temperature greater than 140 C and less than or equal to 180 C.

3. The process according to claim 1, wherein the gas surface reaction is conducted at a temperature greater than or equal to 160 C and less than or equal to 180 C.

4. The process according to claim 1, wherein the gas surface reaction is conducted at a temperature greater than or equal to 160 C and less than or equal to 175 C.

5. The process according to claim 1, wherein the gas surface reaction is conducted at a temperature of 160 C.

6. The process according to claim 1, wherein the gas surface reaction is conducted for less than 1 hour.

7. The process according to claim 1, wherein the gas surface reaction is conducted at a pressure of less than or equal to about 900 mTorr.

8. The process according to claim 1, wherein the gas surface reaction is conducted at a pressure of about 900 mTorr.

9. The process according to claim 1, wherein the gas surface reaction is conducted at a pressure of about 750 mTorr.

10. The process according to claim 1, wherein the gas surface reaction is conducted at a pressure of less than or equal to about 1 mTorr, facilitated by a turbo vacuum pump with a pumping capacity in liters per second (L/s) ranging from 50 L/s to 1000 L/s.

11. The process according to claim 1, wherein the ALD-deposited ZnO is in a ZnO seed layer having a thickness of up to 5 nm.

12. The process according to claim 1, wherein the process is conducted plural times to form a nanolaminates structure.

13. The process according to claim 1, wherein the vapor-deposited ZIF-8 metal organic framework is subjected to chemical mechanical polishing after being formed.

14. The process according to claim 1, wherein the ALD-deposited ZnO is Zn-rich ZnO.

15. The process according to claim 1, wherein the ALD-ZnO+soak cycle further comprises Al, wherein the Al is present in a content <10%.

16. A process for preparing a laminate, comprising:
performing atomic layer deposition (ALD) of zinc oxide as a base between 1 nm to 10 nm in thickness,
exposing 2-methylimidazole vapor phase linker at chemical vapor deposition at a temperature range of greater than 140 C to less than or equal to 180 C in a vacuum condition, and
cycling of the zinc oxide ALD and 2-methylimidazole exposure to deposit a film or fill a gap.

17. The process for preparing a laminate according to claim 16, wherein the zinc oxide is Zn-rich zinc oxide.

18. The process for preparing a laminate according to claim 16, wherein the ALD-ZnO+soak cycle further comprises Al, wherein the Al is present in a content <10%.

19. The process for preparing a laminate according to claim 16, further comprising performing physical vapor deposition (PVD) of Ti prior to performing zinc oxide ALD, wherein the PVD forms a Ti film having a thickness <1 nm.

20. The process for preparing a laminate according to claim 16, wherein the zinc oxide is either at the bottom of features or at the bottom and sidewalls of features only.
